(19) United States
(12) Patent Application Publication
(10) Pub. No.: US 2024/0063401 A1
(43) Pub. Date: Feb. 22, 2024

(54) CONDUCTIVE ELECTROLYTE LAYER AND METHOD OF MANUFACTURING METAL-SUPPORTED SOLID OXIDE FUEL CELL INCLUDING THE SAME

(71) Applicants: Seoul National University R&DB Foundation, Seoul (KR); Foundation of Soongsil University-Industry Cooperation, Seoul (KR)

(72) Inventors: Suk Won CHA, Seoul (KR); Jaewon HWANG, Seoul (KR); Inwon CHOI, Seoul (KR); Taehyun PARK, Seoul (KR)

(73) Assignees: Seoul National University R&DB Foundation, Seoul (KR); Foundation of Soongsil University-Industry Cooperation, Seoul (KR)

(21) Appl. No.: 18/452,172

(22) Filed: Aug. 18, 2023

(30) Foreign Application Priority Data
Aug. 19, 2022 (KR) 10-2022-0104181
Sep. 8, 2022 (KR) 10-2022-0114188

(51) Int. Cl. H01M 4/88; H01M 8/1213; H01M 4/90; H01M 8/1253

(52) U.S. Cl. CPC H01M 4/8885; H01M 8/1213; H01M 4/8871; H01M 4/9033; H01M 4/905; H01M 8/1253; H01M 2008/1293

(57) ABSTRACT

A method of manufacturing a conductive electrolyte layer according to various embodiments of the present disclosure for achieving the objects is disclosed. The method includes loading a substrate into a sputter chamber, connecting a plurality of targets to the chamber, injecting a mixed gas into the chamber, supplying power to each of the plurality of targets and forming a conductive electrolyte layer on one surface of the substrate, and sintering the conductive electrolyte layer at a set sintering temperature.

### CROSS-REFERENCE TO RELATED APPLICATION

This application claims priority to and the benefit of Korean Patent Application No. 10-2022-0104181, filed on Aug. 19, 2022 and Korean Patent Application No. 10-2022-0114188, filed on Sep. 8, 2022 the disclosure of which is incorporated herein by reference in its entirety.

### BACKGROUND

### 1. Field of the Invention

The present disclosure relates to a conductive electrolyte layer and a method of manufacturing a metal-supported conductive ceramic fuel cell including the same, and more specifically, to a method of manufacturing a metal-supported conductive ceramic fuel cell with improved performance by manufacturing a fuel cell through relatively low-temperature dry processes. In addition, the present disclosure relates to a deposition apparatus for forming a conductive electrolyte layer, and the deposition apparatus may control a gas atmosphere, a pressure, a temperature, and the like in a chamber.

### 2. Discussion of Related Art

Recently, as problems of depletion of fossil fuels and waste requiring long-term treatment are coming to the surface, the development of eco-friendly energy conversion apparatuses is attracting attention.

Fuel cells generate about 2.75 times more energy (122 kJ per 1 g of hydrogen) than conventional fossil fuels (e.g., gasoline) and are attracting attention as clean energy sources that do not emit greenhouse gases.

Depending on electrolyte materials used, a fuel cell may be classified into a polymer electrolyte membrane fuel cell (PEMFC) using a polymer ion exchange membrane as an electrolyte, a phosphoric acid fuel cell (PAFC) using liquid phosphoric acid as an electrolyte, an alkaline fuel cell (AFC) using an alkaline electrolyte, a molten carbonate fuel cell (MCFC) using molten carbonate as an electrolyte, a solid oxide fuel cell (SOFC) using solid oxide as an electrolyte, etc. In each fuel cell, a different ion acts as a charge carrier depending on the electrolyte used, and thus an operating environment, a temperature, a necessary catalyst, or the like required for efficient operation of each fuel cell vary.

In particular, the SOFC has various advantages that it not only has high efficiency among various types of fuel cells, but also is able to recycle waste heat generated at a high operating temperature.

Meanwhile, a protonic conductive solid oxide fuel cell (or a protonic ceramic fuel cell (PCFC)), which is one of the SOFCs, can solve by providing high efficiency at a low temperature that the conventional SOFC should solve and thus is attracting attention as a next-generation fuel cell. The PCFC includes a protonic conductive electrolyte and has an advantage that it has a higher ion conductivity than the conventional oxygen ion conductive electrolyte has due to high mobilities of protons in the electrolyte and may be used at a remarkably low temperature.

In general, the PCFC is manufactured through a wet ceramics process, and thus a thermal process at a high temperature is inevitably accompanied. For example, in the wet process, a thermal process at 1400° C. or higher may be necessarily required due to low sinterability of a material.

However, the high-temperature thermal process may cause degradation of cells due to various mechanisms such as the destruction of a micro-structure of the fuel cell, the formation of a secondary phase, etc.

Therefore, in the art, there may be the research and development demand for a technique capable of manufacturing a conductive solid oxide fuel cell to be an ultra-thin film at a relatively low temperature (e.g., 900° C. or lower) using a dry thin film deposition process without using a wet process involving the conventional high-temperature thermal process.

### RELATED ART DOCUMENT

(Patent Document)
(Patent Document 1) Korean Patent Application Laid-Open No. 10-2013-0050401

### SUMMARY OF THE INVENTION

The present disclosure is directed to manufacturing a metal-supported conductive ceramic fuel cell with improved performance by manufacturing a fuel cell by a relatively low-temperature dry process method.

In addition, the present disclosure is directed to providing a fuel cell with finally improved durability and stability by implementing a metal-supported conductive ceramic fuel cell at a low operating temperature to minimize various thermal problems in a process of using the fuel cell.

Objects of the present disclosure are not limited to the above-described objects, and other objects that are not mentioned will be able to be clearly understood by those skilled in the art from the following description.

A method of manufacturing a conductive electrolyte layer according to one embodiment of the present disclosure for achieving the objects is disclosed. The method includes loading a substrate into a sputter chamber, connecting a plurality of targets to the chamber, injecting a mixed gas into the chamber, supplying power to each of the plurality of targets and forming a conductive electrolyte layer on one surface of the substrate, and sintering the conductive electrolyte layer at a set sintering temperature.

In an alternative embodiment, the mixed gas may include argon (Ar) and oxygen (O₂), a composition ratio of oxygen to argon may be in a range of 1:3 to 1:10, and a supply pressure of the mixed gas may be in a range of 3 to 25 m Torr.

In an alternative embodiment, the set sintering temperature may be 900° C. or lower, and a rotation speed of the substrate in the chamber may be 900 RPM or less.

In an alternative embodiment, the conductive electrolyte layer may be a BZY composite formed through a deposition process, and the BZY composite may be a barium zirconate composite (Y:BaZrO₃) doped with yttrium.

In an alternative embodiment, a composition ratio of each of barium (Ba), zirconium (Zr), and yttrium (Y) in the BZY composite may be in a range of 1:0.8:0.2 to 1:0.9:0.1.

In an alternative embodiment, the plurality of targets may include a first target including BaCO₃, a second target including ZrO₂, and a third target including Y₂O₃, and the power applied to each of the plurality of targets may be in a range of 20 to 200 W.

In an alternative embodiment, the power supplied to the first target may be in a range of 70 to 100 W, the power supplied to the second target may be in a range of 50 to 80 W, and the power supplied to the third target may be in a range of 20 to 60 W.

In an alternative embodiment, the conductive electrolyte layer may be deposited on the one surface of the substrate in a thickness of smaller than 2 μm, and a deposition area may be 2×2 cm² or more.

A method of manufacturing a conductive electrolyte layer according to another embodiment of the present disclosure is disclosed. The method includes supplying power to each of a plurality of targets and forming an electrolyte layer on one surface of a substrate, and sintering the electrolyte layer at a set sintering temperature, wherein the set sintering temperature is 900° C. or lower.

A method of manufacturing a metal-supported solid oxide fuel cell including a conductive electrolyte layer according to still another embodiment of the present disclosure is disclosed. The method includes providing a metal support, forming an anode layer on one surface of the metal support, forming the conductive electrolyte layer on one surface of the anode layer, and forming a cathode layer on one surface of the conductive electrolyte layer.

In an alternative embodiment, in the metal-supported solid oxide fuel cell, the anode layer, the electrolyte layer, and the cathode layer may be sequentially formed through dry processes on the one surface of the metal support in a chamber.

In an alternative embodiment, at least a portion of the metal support may be made of a porous metal, and the metal support may support the anode layer, the electrolyte layer, and the cathode layer.

In an alternative embodiment, the forming of the anode layer may include loading the metal support into a chamber, connecting a plurality of targets to the chamber, injecting a mixed gas into the chamber, and supplying power to at least one of the plurality of targets and depositing the anode layer on the one surface of the metal support.

In an alternative embodiment, each of the plurality of targets may include any one of NiO, BaCO₃, Y₂O₃, ZrO₂, and LSCF.

In an alternative embodiment, the mixed gas may include argon (Ar) and oxygen (O₂), a composition ratio of oxygen to argon may be in a range of 1:3 to 1:10, and a supply pressure of the mixed gas may be in a range of 3 to 25 m Torr.

In an alternative embodiment, the forming of the conductive electrolyte layer may further include supplying power to at least one of the plurality of targets and depositing an electrolyte layer on one surface of a substrate, and performing sintering at a preset sintering temperature, the preset sintering temperature may be 900° C. or lower, and a rotation speed of the substrate in the chamber may be 900 RPM or less.

In an alternative embodiment, the conductive electrolyte layer may be a BZY composite formed through a deposition process, and the BZY composite may be a barium zirconate composite (Y:BaZrO₃) doped with yttrium.

In an alternative embodiment, a composition ratio of each of barium (Ba), zirconium (Zr), and yttrium (Y) in the BZY composite may be in a range of 1:0.8:0.2 to 1:0.9:0.1.

In an alternative embodiment, the cathode layer may be deposited on the one surface of the conductive electrolyte layer and may be an LSCF-BZY composite generated as a result of cosputtering using at least one of the plurality of targets.

In an additional embodiment of the present disclosure, a metal-supported solid oxide fuel cell including a conductive electrolyte layer is disclosed. The fuel cell includes a metal support, an anode layer formed on one surface of the metal support, the conductive electrolyte layer formed on one surface of the anode layer, and a cathode layer formed on one surface of the conductive electrolyte layer, wherein the conductive electrolyte layer may be a barium zirconate composite (Y:BaZrO₃) doped with yttrium.

In an additional embodiment of the present disclosure, a conductive electrolyte layer is disclosed. The conductive electrolyte layer includes a barium zirconate composite (Y:BaZrO₃) doped with yttrium, wherein the barium zirconate composite is formed by being deposited through cosputtering using a plurality of targets.

Other detailed matters of the present disclosure are included in a detailed description and drawings.

### BRIEF DESCRIPTION OF THE DRAWINGS

Various aspects are now described with reference to the drawings, in which similar reference numbers are used to collectively denote similar elements. In the following embodiments, for the purpose of description, numerous specific details are suggested to provide the overall understanding of one or more aspects. However, it will be apparent that such aspect(s) may be practiced without these specific details.

FIG. 1 is an exemplary view for describing fuel cells variously classified according to types of supports according to one embodiment of the present disclosure.

FIG. 2 is a schematic diagram illustrating a basic operating principle of an oxygen ion conductive electrolyte-based fuel cell and a ceramic electrolyte-based fuel cell.

FIG. 3 is an exemplary view for describing a thin film deposition process using sputtering according to one embodiment of the present disclosure.

FIG. 4 is a view illustrating an exemplary flowchart of a method of forming a conductive electrolyte layer according to one embodiment of the present disclosure.

FIG. 5 is a view exemplarily illustrating a sputtering chamber according to one embodiment of the present disclosure.

FIG. 6 is an exemplary cross-sectional view of the sputtering chamber according to one embodiment of the present disclosure.

FIG. 7 is a view exemplarily illustrating a process of forming an electrolyte film through co-sputtering according to one embodiment of the present disclosure.

FIG. 8 is an exemplary view for describing a substrate rotation speed (SRS) and a target-substrate distance (TSD) in a sputtering process according to one embodiment of the present disclosure.

FIGS. 9A and 9B are an exemplary view related to a change in a micro-structure of a thin film according to one embodiment of the present disclosure.

FIGS. 10, 11A and 11B are views illustrating experimental results related to aspects of the change in the micro-structure of the thin film according to changes in power and a deposition pressure of a gas.

FIG. 12 is a view illustrating experimental results obtained by measuring a composition ratio of a conductive electrolyte layer formed as a result of performing actual co-sputtering.

FIG. 13 is a view illustrating an exemplary flowchart of a method of manufacturing a metal-supported solid oxide fuel cell including the conductive electrolyte layer according to one embodiment of the present disclosure.

FIG. 14 is an exemplary cross-sectional view of the metal-supported solid oxide fuel cell including the conductive electrolyte layer according to one embodiment of the present disclosure.

FIG. 15 is a view illustrating an exemplary flowchart of a method of forming a conductive electrolyte layer according to another embodiment of the present disclosure.

FIG. 16 is a view exemplarily illustrating a process of forming an electrolyte film through co-sputtering according to another embodiment of the present disclosure.

### DETAILED DESCRIPTION OF EXEMPLARY EMBODIMENTS

Various embodiments and/or aspects are now disclosed with reference to the accompanying drawings. In the following description, for the purpose of description, numerous specific details are disclosed to facilitate the overall understanding of one or more aspects. However, it will also be detected by those skilled in the art that such aspect(s) may be practiced without these specific details. The following description and the accompanying drawings describe in detail specific exemplary aspects of one or more aspects. However, these aspects are exemplary, and some of various methods in principles of various aspects may be used, and the described descriptions are intended to include all such aspects and their equivalents. Specifically, “embodiment,” “example,” “aspect,” “exemplary,” and the like used herein may not be construed as indicating that any aspect or design described is superior to or advantageous over other aspects or designs.

Hereinafter, the same reference numerals are given to the same or similar elements regardless of reference numerals, and overlapping descriptions thereof will be omitted. In addition, in describing the embodiments disclosed in the specification, when it is determined that a detailed description of a related known technology may obscure the gist of the embodiments disclosed in the specification, a detailed description thereof will be omitted. In addition, the accompanying drawings are only for easy understanding of the embodiments disclosed in the specification, and the technical spirit disclosed in the specification is not limited by the accompanying drawings.

Although first, second, and the like are used to describe various devices or elements, it goes without saying that these devices or elements are not limited by these terms. These terms are only used to distinguish one device or element from another device or element. Therefore, it goes without saying that a first device or element mentioned below may be a second device or element within the technical spirit of the present disclosure.

Unless otherwise defined, all terms (including technical and scientific terms) used in the specification may be used as meaning commonly understood by those skilled in the art to which the present disclosure pertains. In addition, terms defined in commonly used dictionaries are not construed ideally or excessively unless clearly and specially defined.

In addition, the term “or” is intended to mean an inclusive “or” rather than an exclusive “or.” In other words, unless otherwise specified or clear from the context, “X uses A or B” is intended to mean one of the natural inclusive substitutions. In other words, when X uses A, X uses B, or X uses both A and B, “X uses A or B” may be applied to any of these cases. In addition, it should be understood that the term “and/or” as used in the specification should be understood to indicate and include all possible combinations of one or more of the listed related items.

In addition, it should be understood that the terms “comprises” and/or “comprising” mean that the corresponding feature and/or element is present, but does not exclude the presence or addition of one or more other features, elements, and/or groups thereof. In addition, unless otherwise specified or clear from the context indicating a singular form, a singular form in the specification and the claims should generally be construed as meaning “one or more.”

When a first element is described as being “connected” or “coupled” to a second element, it should be understood that the first element may be directly connected or coupled to the second element, but a third element may also be present therebetween. On the other hand, when a first element is described as being “directly connected” or “directly coupled” to a second element, it should be understood that a third element is are present therebetween.

The terms “module” and “unit” for elements used in the following description are given or used interchangeably in consideration of ease of preparing the specification and not have meanings or roles that are distinct from each other by themselves.

When an element or a layer is described as being “on” another element or layer, it means not only a case in which the element or the layer is disposed directly on another element or layer, but also a case in which other layers or elements are interposed therebetween. On the other hand, when an element is described as “directly on,” it indicates that no other elements or layers are interposed therebetween.

The spatially relative terms “below,” “beneath,” “lower,” “above,” “upper,” and the like may be used to easily describe one element or the correlation with other components as illustrated in the drawings. The spatially relative terms should be understood as including different directions of elements in use or operation in addition to the directions illustrated in the drawings.

For example, when elements illustrated in the drawing are overturned, a first element described as being disposed “below” or “beneath” a second element may be disposed “above” the second element. Therefore, the exemplary term “below” may include both downward and upward directions. Elements may also be oriented in other orientations, and thus the spatially relative terms may be construed according to the orientations.

Objects and effects of the present disclosure, and technical configurations for achieving them will become clear with reference to the embodiments described below in detail with reference to the accompanying drawings. In describing the present disclosure, when it is determined that a detailed description of the known function or technology may unnecessarily obscure the gist of the present disclosure, a detailed description thereof will be omitted. In addition, the terms to be described below are the terms defined in consideration of functions in the present disclosure, which may vary depending on the intention or custom of a user or an operator.

However, the present disclosure is not limited to the embodiments disclosed below and may be implemented in various different forms. These embodiments are provided only to make the present disclosure complete and completely inform those skilled in the art to which the present disclosure pertains of the scope of the disclosure, and the present disclosure is only defined by the scope of the claims. Therefore, the definition should be made based on the contents throughout the specification.

Since the Industrial Revolution, the development of energy systems based on fossil fuels has continued worldwide, and greenhouse gases emitted from the use of fossil fuels have caused global warming and various environmental problems such as causing abnormal climate phenomena.

Therefore, in many countries in the world, continuous research is being conducted to change a fossil fuel-based energy system that causes environmental pollution into a renewable energy-based technology. Since renewable energy production is greatly affected by nature, power production fluctuates greatly depending on time, weather, and region, and thus it is difficult to predict an amount of power generated.

Fuel cells have advantages in that they generate more energy than conventional fossil fuels and do not emit greenhouse gases, and it is easy to predict the amount of power generated. Depending on electrolyte materials used, a fuel cell may be classified into a polymer electrolyte membrane fuel cell (PEMFC) using a polymer ion exchange membrane as an electrolyte, a phosphoric acid fuel cell (PAFC) using liquid phosphoric acid as an electrolyte, an alkaline fuel cell (AFC) using an alkaline electrolyte, a molten carbonate fuel cell (MCFC) using molten carbonate as an electrolyte, a solid oxide fuel cell (SOFC) using solid oxide as an electrolyte, etc. In each fuel cell, a different ion acts as a charge carrier depending on the electrolyte used, and thus an operating environment, a temperature, a necessary catalyst, or the like required for efficient operation of each fuel cell vary.

Meanwhile, the PEMFC, the PAFC, and the AFC, which operate at a relatively low temperature, require a platinum catalyst, and when there is no separate modifying agent, have a disadvantage in that they may use only high-purity hydrogen as a fuel. On the other hand, the SOFC may use a relatively inexpensive ceramic material as a catalyst and use fossil fuels, such as natural gas, LPG, and butane gas, which are widely used in the past, and biofuels as a fuel without a separate modifying agent.

In particular, the SOFC has various advantages in that it has high efficiency among various types of fuel cells, but also is able to recycle waste heat generated at a high operating temperature after generating electricity through the fuel cell.

The SOFC is a system for directly converting chemical energy into electrical energy, and a solid oxide electrolytic cell (SOEC) is a system capable of storing chemical energy (hydrogen, ammonia, methane, or the like) by injecting electrical energy through the reverse reaction of the SOFC. In other words, when electricity generated from renewable energy exceeds the demand for power, idle power may be stored in the form of chemical materials, such as hydrogen, through electrolysis, and when the generated electricity is less than the demand for power, the fuel cell may be operated to supply power with high efficiency. The SOFC is known as a technique that may promote the stabilization of renewable energy by supplying high-quality electricity according to electricity demand and at the same time, storing idle power. In particular, compared to the conventional battery technology-based energy storage system (ESS) for storing energy inside a cell, the SOEC technique has an advantage in that it is able to be used as a large-capacity energy storage system of one MWh scale or more because it uses to store energy based on chemical energy such as hydrogen that may be easily moved and stored.

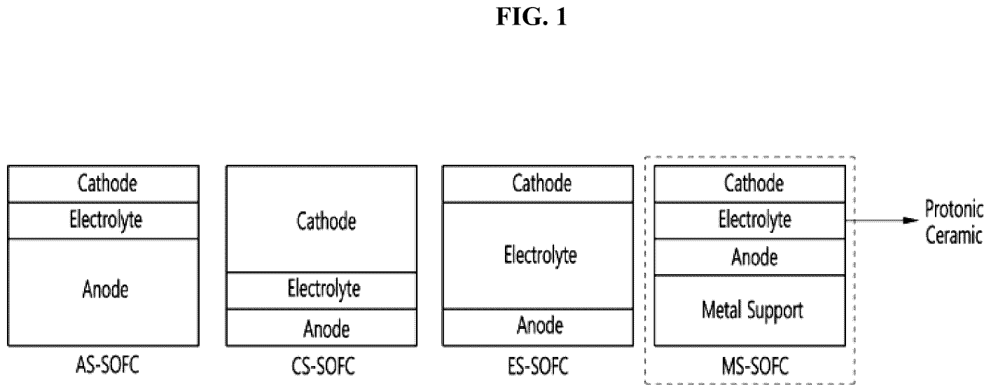

As illustrated in FIG. 1, the SOFC may be variously classified according to the types of supports. An AS-SOFC is an anode support type SOFC as a type of a SOFC using an anode layer, that is, an anode as a support, a CS-SOFC is a cathode support type SOFC as a type of a SOFC using a cathode layer, that is, a cathode as a support, and an ES-SOFC is an electrolyte support type SOFC as a type of a SOFC using an electrolyte layer as a support.

According to the embodiment, the present disclosure may relate to a metal-supported protonic ceramic fuel cell (MS-PCFC) having a higher strength and a stronger feature against thermal impact compared to the AS-SOFC, the CS-SOFC, and the ES-SOFC. The MS-PCFC is one of the types of the SOFCs and may be configured in the form of a metal substrate supporting an anode, an electrolyte, and a cathode.

The MS-PCFC has a structure that maximizes mechanical reliability by supporting components of the SOFC, such as an anode, an electrolyte, and a cathode, by porous metal and has an advantage in that it may minimized thicknesses of the electrolyte and the anode, which are the cause of ohmic loss and thus have a lower operating temperature than other types of SOFCs have. In a specific embodiment, the AS-SOFC has characteristics that are vulnerable to degradation phenomena of cell components and redox repetition due to a high-temperature operation, but the MS-PCFC may overcome the characteristics through a low operating temperature.

In particular, the protonic conductive electrolyte has an advantage in that it has a higher ion conductivity than the conventional oxygen ion conductive electrolyte has due to high mobilities of protons and may be used at a remarkably low temperature. When the operating temperature of the fuel cell is low, it is possible to prevent degradation of cells, which may act as a factor of improving long-term durability.

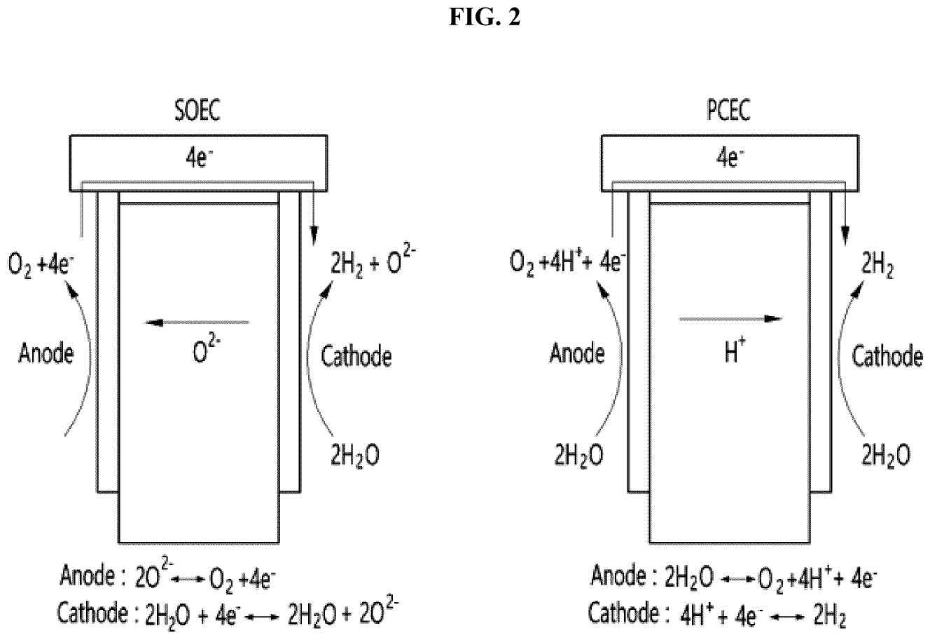

FIG. 2 is a schematic diagram illustrating a basic operating principle of an oxygen ion conductive electrolyte-based fuel cell and a protonic ceramic electrolyte-based fuel cell. Both fuel cells are manufactured in a structure in which a high-density ion conductive solid electrolyte is positioned in the middle and porous electrodes are disposed at both ends. The electrodes require a sufficiently porous structure for efficient diffusion of gaseous reactants and products and require good electrical conductivity. In addition, the electrolyte may realize high performance only when it is structurally dense and formed in a small thickness to minimize an ohmic resistance. As illustrated in FIG. 2, it can be confirmed that fuel electrode reaction equations of the SOEC and the PCEC are different. In other words, the reaction mechanism for generating hydrogen in each fuel cell may be different.

In the SOEC, water supplied to an anode is dissociated into hydrogen and oxygen by electrical energy applied from the outside to generate hydrogen at the cathode, and oxygen ions may move through the electrolyte to generate oxygen at an anode. Unlike the SOEC, the PCEC is characterized in that it may generate a high-purity dry hydrogen fuel that is not diluted by water because hydrogen ions generated by supplying water at the oxygen anode move through the electrolyte to generate hydrogen at the anode. In the embodiment, the PCEC may be operated at a lower temperature than the SOEC is operated and has excellent scalability because it may use various industrial waste heat sources.

In addition, when a metal support is used, it is characterized in that it is free to change an operating environment due to rapid start-up and output fluctuation due to toughness against thermal impact. Therefore, it may be advantageous in terms of commercialization such as compactness and light weight.

According to one embodiment, the MS-PCFC has conventionally been manufactured through a wet ceramics process. However, in the wet process, a thermal process at 1400° C. or higher may be necessarily required due to low sinterability of a material. The high-temperature thermal process may cause degradation of cells due to various mechanisms such as the destruction of a micro-structure of the fuel cell, the formation of a secondary phase, etc.

More specifically, in general, BaZrO₃ and BaCeO₃ are widely used as protonic conductive ceramics. In the embodiment, the sinterability of BaZrO₃ may be relatively lower than that of BaCeO₃. BaCeO₃ requires a sintering temperature of 1400 to 1450° C. for a sintered density of 95% or more, while BaZrO₃ requires a high sintering temperature of 1600° C. or higher. For example, when the sintering temperature is high, the evaporation of Ba may result in formation of a secondary phase such as ZrO₂ having low ionic conductivity. In addition, due to low sinterability, grain growth is not sufficiently implemented even at a temperature of 1600° C. or higher, and thus there is a disadvantage in that a grain boundary resistance is high.

In other words, the MS-PCFC has various advantages such as low operating temperature, structural stability, redox stability, high output, and low price, but there are various factors that hinder performance of fuel cells, such as interfacial reaction between a metal support and a ceramic, chemical stability of an electrolyte, a sintering temperature and limitation of a sinterability, and a process of preparing an electrolyte of a dense thin film.

The present disclosure is directed to minimizing factors that hinder performance of the corresponding fuel cell in a process in providing the MS-PCFC that may have a remarkably lower operating temperature and is advantageous in terms of commercialization. More specifically, since the MS-PCFC (or an MS-SOFC including a protonic conductive electrolyte layer) according to the present disclosure is manufactured in a low-temperature process of 900° C. or lower in a manufacturing process, it is possible to prevent the destruction of a micro-structure, the generation of a secondary phase, and the like, and since the MS-PCFC may be operated at the low operating temperature (e.g., 550° C. or lower), it is possible to prevent degradation of components and at the same time, provide high performance.

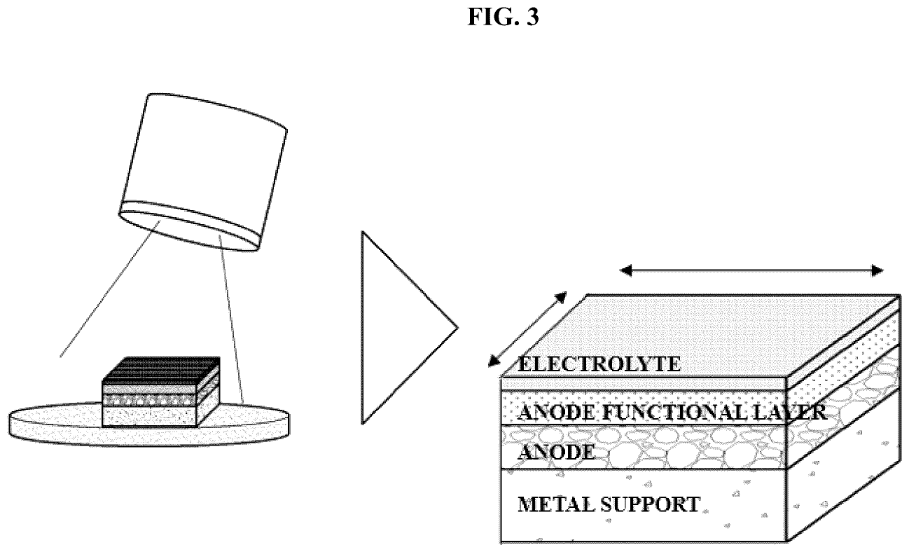

According to one embodiment of the present disclosure, as illustrated in FIG. 3, the conductive electrolyte layer may be formed through a thin film deposition process using sputtering. In addition, the MS-SOFC including the conductive electrolyte layer may be formed through a thin film deposition process using sputtering. Referring to FIG. 3, the sputtering process is a deposition process performed in a vacuum state and may be a process of depositing a material to be deposited on one surface of a substrate (or an anode) by applying an electric field to a material to be deposited and a portion (e.g., the substrate or the anode) on which a film will be formed, generating plasma, which is a fourth material state, therebetween, and allowing argon ions to hit metal while moving toward a target connected to a negative (−) pole to induce bounced metal particles to accumulate on a base layer disposed at an opposite side. According to one embodiment, the present disclosure may be characterized in that a thin film is deposited on one surface of the substrate (or the anode) through a co-sputtering process using multiple targets. As described above, when the thin film is deposited through the sputtering process, unlike the wet process, there is an advantage in that a high sintering temperature (e.g., 1400° C. or higher) is not required, thereby enabling forming ultra-thin film. As the electrolyte layer is made thinner, an ohmic resistance can be minimized to realize high performance, and thus the sputtering process of enabling forming ultra-thin film may be advantageous for improving performance of the fuel cell. In addition, the sputtering process has an advantage in that it has a relatively lower manufacturing cost and it is advantageous for manufacturing a large-area cell.

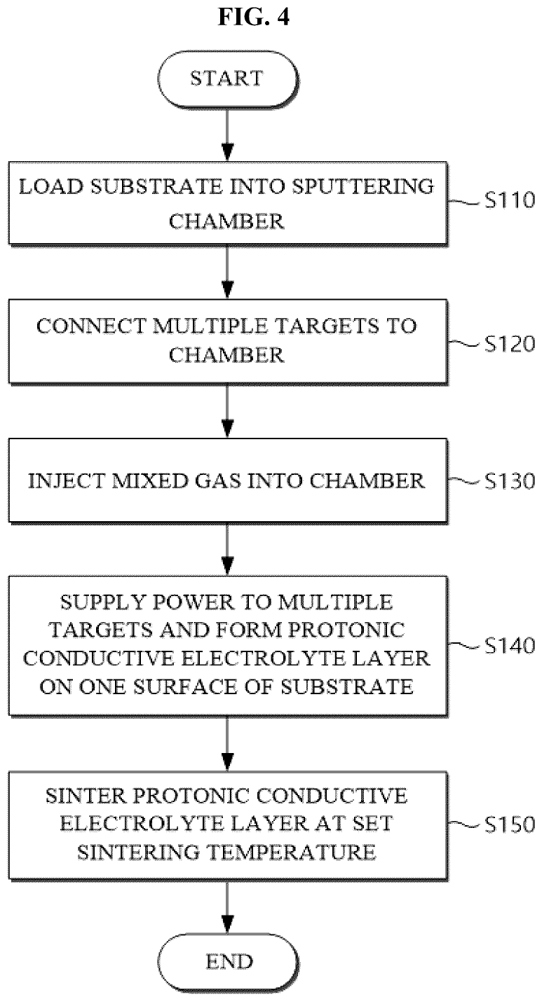

A specific manufacturing process method of the conductive electrolyte layer and the MS-SOFC will be described below with reference to FIGS. 4 to 16.

FIG. 4 is a view illustrating an exemplary flowchart of a method of forming a conductive electrolyte layer according to one embodiment (e.g., a first embodiment) of the present disclosure. The order of operations illustrated in FIG. 4 may be changed, as necessary, and at least one operation may be omitted or added. In other words, the operations of FIG. 4 are only one embodiment of the present disclosure, and the scope of the present disclosure is not limited thereto.

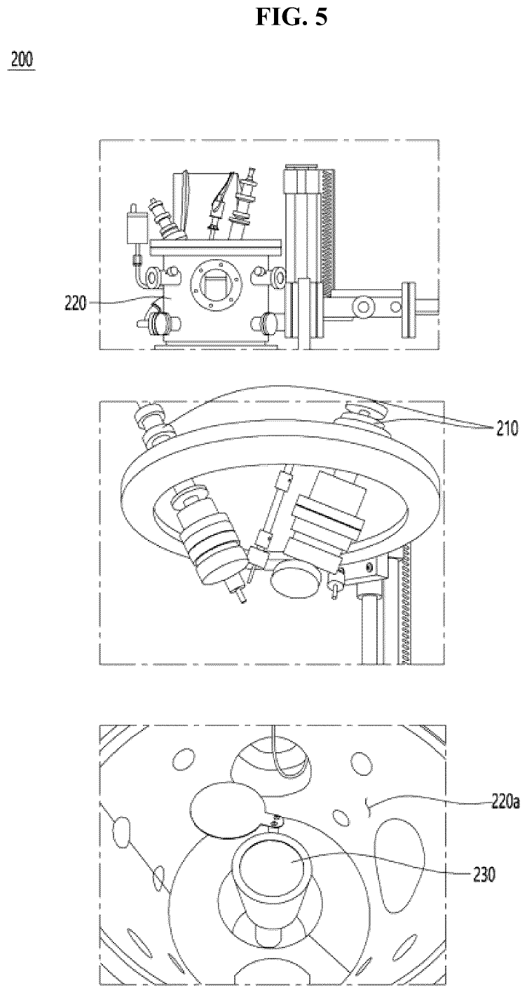

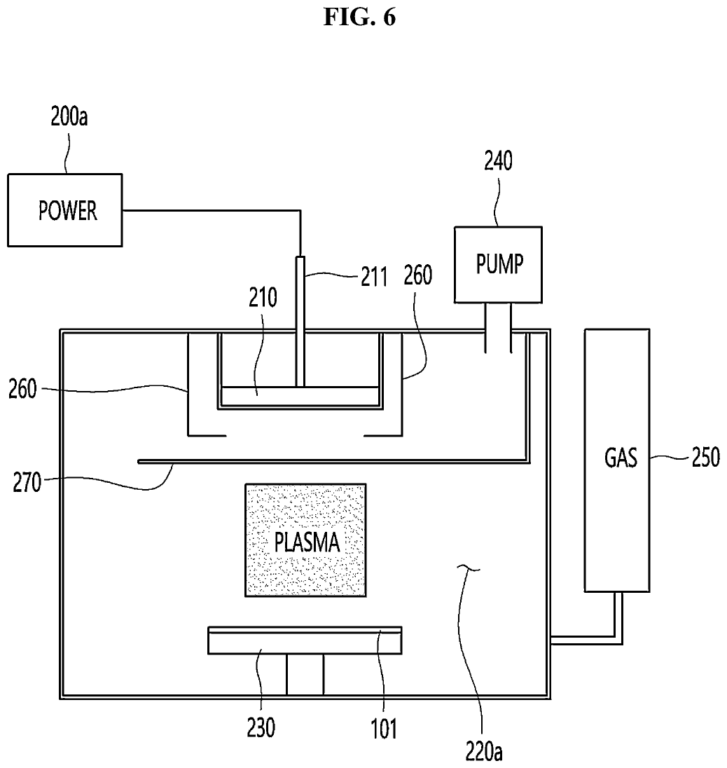

According to one embodiment of the present disclosure, the method of forming a conductive electrolyte layer may include loading a substrate into a sputtering chamber (S110). It may be characterized in that a conductive electrolyte layer 130 according to the present disclosure is formed through a sputtering process. Referring to FIGS. 5 and 6, an inner space 220a may be present in a sputtering chamber 220, and a substrate 101 may be positioned at an upper side of a support 230 provided in the inner space 220a. In one embodiment, the substrate 101 may mean a plate on which the conductive electrolyte layer 130 is deposited. The substrate 101 may be made of various materials depending on the purpose of use. For example, an anode layer may be used as a substrate. In the embodiment, a heater for heating the substrate 101 or a cooling unit for cooling the substrate 101 may be provided under the substrate 101. In addition, in the embodiment, the substrate 101 may be provided to be rotated for uniform deposition.

When the substrate is positioned in the inner space 220a of the sputtering chamber 220, multiple targets may be positioned at an upper portion of the inner space 220a. Describing this in more detail with reference to FIG. 6, a pump 240 may make the inner space 220a of the chamber 220 into a vacuum state. Since sputtering should be performed in a vacuum state, condensed air may be discharged through the pump 240 to maintain the vacuum state in the inner space 220a. In a state in which the substrate is loaded into the chamber 220, the inner space 220a may be maintained in the vacuum state through the pump 240.

In the embodiment, a power supply unit 200a may mean a power supply for supplying power to a negative electrode. The power supply unit 200a may be related to direct current (DC) power and alternating current (AC) power. In a specific embodiment, the power supply unit 200a may use a high frequency (RF) AC power having a preset frequency.

In one embodiment, a gun may be an assembly that mounts a target and is connected to a power supply to act as a negative electrode. Cooling water for cooling the target flows inside the gun, and a wire for receiving power from the power supply unit 200a may be provided therein. The gun may be connected to the target and may perform cooling and supplying power in direct contact with the target.

The target may be a material for coating the substrate 101. The present disclosure may perform co-sputtering using multiple targets 210, and each of the multiple targets may be related to BaCO₃, Y₂O₃, and ZrO₂. The target is mounted on (or connected to) the gun to substantially function as a surface of the negative electrode, and ions generated from the plasma collide with the target connected to the negative electrode. In this case, as atoms and molecules on the surface of the target bounce off and accumulate on the substrate positioned at an opposite side, a material related to the target is deposited on the substrate.

A shutter 270 may function to mask between the substrate 101 and the target. For example, the shutter 270 may instantaneously block between the substrate 101 and the target in order to perform deposition for a desired time.

A gas supply unit 250 may supply gases into the chamber. Here, a gas supplied by the gas supply unit 250 may be related to an argon gas. In a more specific embodiment, the gas supply unit 250 may supply a mixed gas in which argon and oxygen are mixed at a preset ratio into the chamber. The gas supply unit 250 may include a gas supply module in correspondence to each gas. For example, the gas supply unit 250 may include a first gas supply module corresponding to argon and a second gas supply module corresponding to oxygen. A mass flow controller (MFC) may be provided in each gas supply module, and thus an accurate amount of gas may be injected into the chamber. For example, the MFC may control the supply of an accurate amount of gas (e.g., argon and oxygen) into the chamber by measuring an amount of gas in a unit of sccm. In addition, a shield may be provided on a portion of an outer circumferential surface of the target. A shield 260 may be provided to allow sputtering to be performed on only a desired portion of the connected target and maintain stability of discharge.

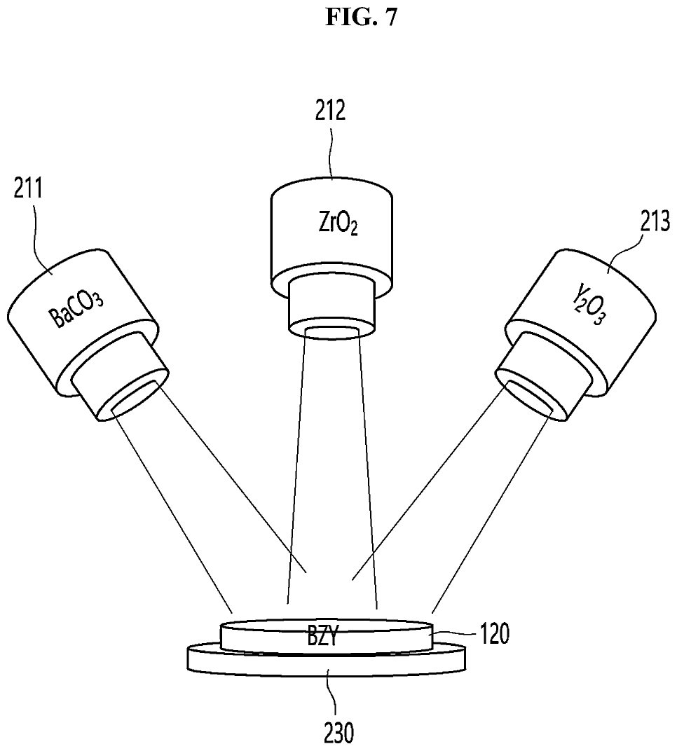

In addition, the method of forming a conductive electrolyte layer may include connecting the multiple targets to the chamber (S120). According to the embodiment, as illustrated in FIG. 7, the multiple targets may include a first target 211 containing BaCO₃, a second target 212 containing ZrO₂, and a third target 213 containing Y₂O₃. In other words, according to the present disclosure, the conductive electrolyte layer 130 may be formed through co-sputtering using the multiple targets 210.

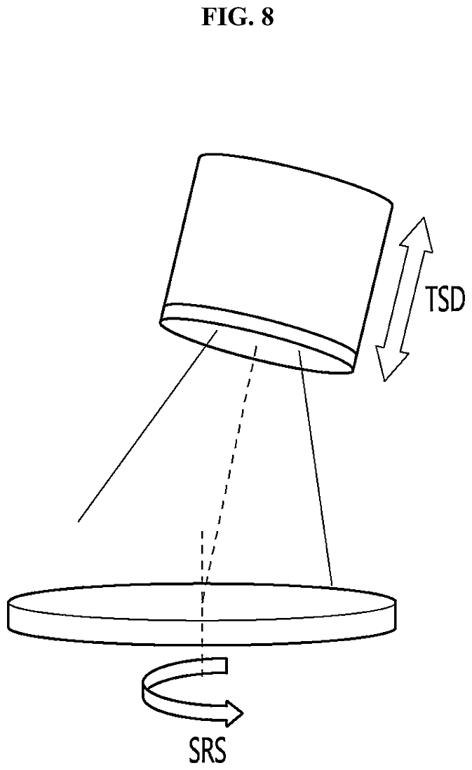

In the embodiment, it may be characterized in that a substrate rotation speed (SRS) in the chamber may be 900 RPM or less. The substrate 101 may be a plate on which the conductive electrolyte layer 130 is deposited, and the substrate 101 may be rotated for uniform deposition in a deposition process. Specifically, referring to FIG. 8, the substrate 101 may be rotated based on a rotational axis related to a central portion of the substrate 101. Here, the corresponding SRS may be 900 RPM or less. Limiting the SRS may be a set condition for uniformly depositing the conductive electrolyte layer 130 on the substrate. In a specific embodiment, when the SRS exceeds 900 RPM, performance of the formed electrolyte layer can be reduced because materials related to each target are not uniformly distributed in various regions. In other words, it may be characterized in that an optimal SRS for maintaining a density of the electrolyte layer may be 900 RPM or less.

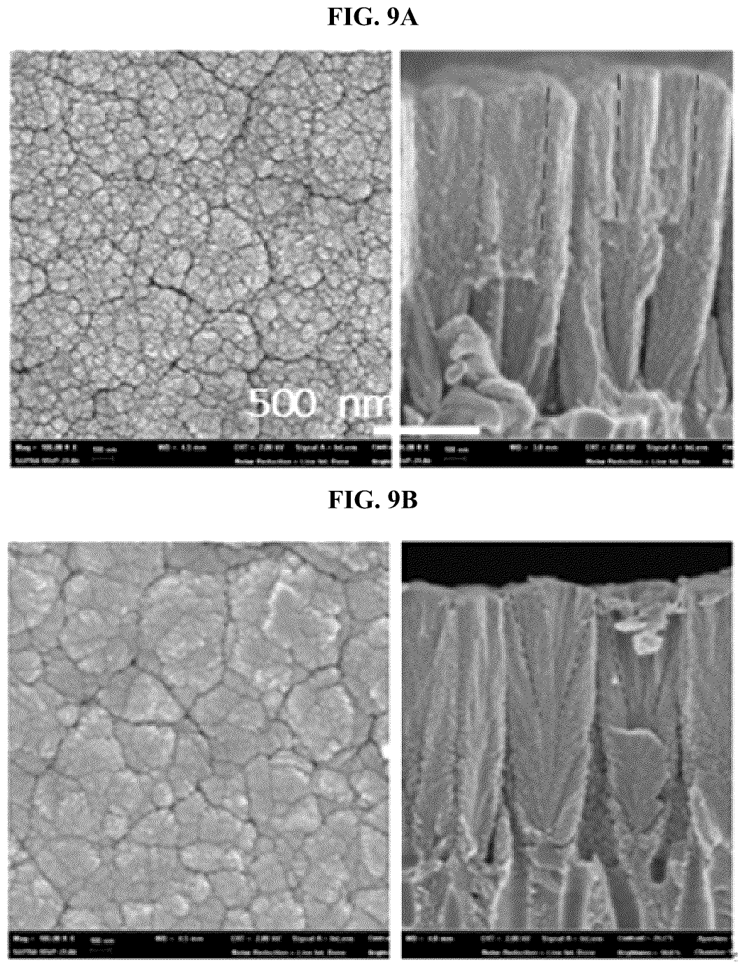

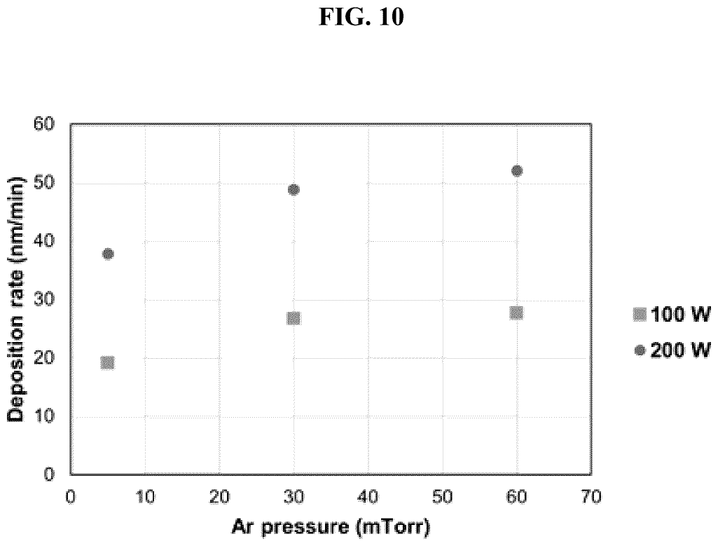

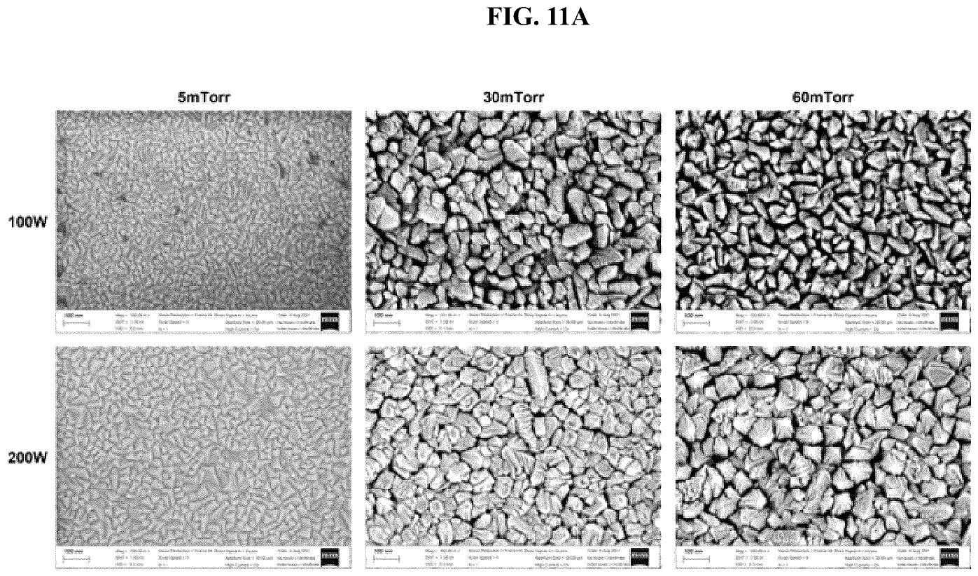

In one embodiment, it may be characterized in that a distance (target-substrate distance (TSD)) between the target and the substrate 101 may be 7 to 13 cm or less. Specifically, referring to FIG. 8, a composition ratio of the deposited composition (i.e., the conductive electrolyte layer) may vary depending on the distance between the target and the substrate 101. In particular, the conductive electrolyte layer according to the present disclosure is a composite related to BZY, and since the BZY is a complex multi-component material, it is difficult to constantly maintain the composition ratio during sputtering. In the embodiment, an incident angle may vary depending on the TSD. In other words, incident angles of sputtering particles may also vary as the TSD varies, and thus a shape of a columnar structure may be changed. In other words, when the TSD is smaller than 7 cm or exceeds 13 cm, the composition formed at the upper side of the substrate may not maintain an appropriate composition ratio, and thus the performance of the formed conductive electrolyte layer may be degraded. In other words, for an optimal composition ratio of the composition for improving the density of the electrolyte layer, an appropriate distance between the target and the substrate may be in a range of 7 cm to 13 cm. As a more specific example, FIG. 9B may be a case in which the TSD is smaller than that of FIG. 9A. Referring to FIG. 10, it can be confirmed that as the TSD decreases, the conventional vertical columnar structure has a trapezoidal columnar cross-sectional structure. When the trapezoidal columnar thin film cross-sectional structure is formed, it is possible to manufacture a dense electrolyte even with a small thickness.

In addition, in the embodiment, it may be characterized in that threshold distance ranges for a distance between each of the multiple targets and the substrate 101 are different. Since each target is related to a different material, a speed and a mass at which the material is deposited on the substrate may be different for each target. According to the present disclosure, in order to manufacture an electrolyte layer having a preset density and electrical conductivity and improved durability, distances between each of the multiple targets and the substrate may be differently determined. For example, a distance between the substrate 101 and the first target related to BaCO₃ may be 7 cm, a distance between the substrate 101 and the second target 212 related to ZrO₂ may be 10 cm, and a distance between the third target 213 related to Y₂O₃ and the substrate 101 may be 12 cm. The specific numerical description related to the described distances between each target and the substrate is only an example, and the present disclosure is not limited thereto. In other words, according to the present disclosure, the electrolyte layer having the preset density and electrical conductivity and improved durability may be formed by differently determining the distances from the substrate for each target.

In addition, the method of forming a conductive electrolyte layer may include injecting a mixed gas into the chamber (S130). In the embodiment, the mixed gas may include argon and oxygen. The composition ratio of oxygen to argon in the mixed gas may be in a range of 1:3 to 1:10. In other words, argon in the mixed gas may be provided to have a capacity of 3 to 10 times greater than that of oxygen.

More specifically, during co-sputtering, carbon (C) may be generated from BaCO₃ related to the first target 211, and the generated C may be contained in a BZY composite as an impurity. Therefore, an oxygen partial pressure may be adjusted to prevent C from entering the electrolyte film as an impurity. When the oxygen partial pressure is adjusted, C may be blown away as volatile CO₂ and not contained in the membrane as an impurity. As a specific example, as the oxygen partial pressure increases, C may be better removed. However, when the oxygen partial pressure is too high, a deposition rate is significantly reduced, and thus an oxygen ratio in the mixed gas may be in a range of 10 to 30%. In other words, a minimum oxygen ratio may be 10%, and a maximum oxygen ratio may be 30%. When there is a large amount of oxygen, an amount of oxygen larger than that of stoichiometry may enter the electrolyte film. Therefore, in order to match stoichiometry, oxygen should be neither too much nor too little. In the embodiment, as a method of adjusting supplied oxygen, there are a method of increasing the oxygen partial pressure by increasing the oxygen ratio at the same pressure and a method of increasing the oxygen partial pressure by increasing only the deposition pressure at the same oxygen ratio. In a more specific embodiment, the deposition pressure (or the supply pressure) of the mixed gas may be in a range of 3 to 25 m Torr.

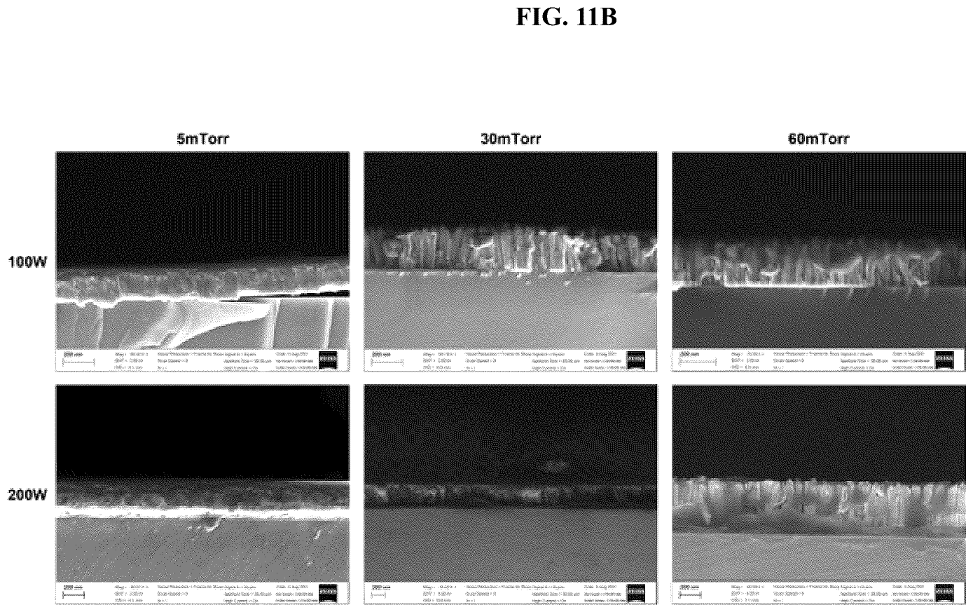

FIGS. 10 and 11 are views illustrating experimental results related to aspects of the change in the micro-structure of the thin film according to changes in power and a deposition pressure of a gas. In experiments illustrated in FIGS. 10 and 11, a change in the deposition rate of the deposited membrane was recorded by applying power of 100 W and 200 W and changing the deposition pressure at 5, 30, and 60 m Torr in correspondence to each power, and the experiments were performed by a method of checking states of a surface and side sections of the deposited membrane.

Referring to FIG. 10, as the deposition pressure and the applied power (i.e., the power), the deposition rate may increase. In addition, in the embodiment, when a metal material is deposited, as the deposition pressure increases, a probability of the sputtered particles colliding with the background gas before reaching the substrate and thus losing energy may increase. A metal adatom reaching the substrate after losing energy as described above does not have enough energy to be spread to the surface, and thus may grow as soon as it reaches the substrate and may be formed of porosity. Conversely, when the deposition pressure is low, the metal adatom may be spread on the surface and grow densely while canceling the shadowing effect. With the same principle, when the applied power increases, metal particles are sputtered to increase energies thereof, and thus may be configured more densely, and when the applied power decreases, the metal particles may grow more porous. In this regard, referring to FIG. 11, as illustrated in FIG. 11A, it can be confirmed that the applied power increases, the surface is densely formed. In addition, as illustrated in FIG. 11B, it can be confirmed that the deposition pressure decreases, the porosity can be further improved. In other words, variables related to the applied power applied to each of the multiple targets and the deposition pressure of the mixed gas may be very important factors in manufacturing the electrolyte layer according to the present disclosure.

According to one embodiment of the present disclosure, the method of forming a conductive electrolyte layer may include forming the conductive electrolyte layer on one side of the substrate by supplying power to each of the multiple targets (S140).

According to the embodiment, the present disclosure may be characterized by performing the co-sputtering process using the multiple targets. According to one embodiment, the conductive electrolyte layer 130 may be the BZY composite formed through the deposition process using the multiple targets. It may be characterized in that the BZY composite is a barium zirconate composite (Y:BaZrO₃) doped with yttrium. It may be characterized in that a composition ratio of barium, zirconium, and yttrium in the BZY composite is in a range of 1:0.8:0.2 to 1:0.9:0.1. The present disclosure is directed to forming the electrolyte layer related to the BZY composite that is thin and dense, has improved performance, and may be operated even at a medium-low temperature.

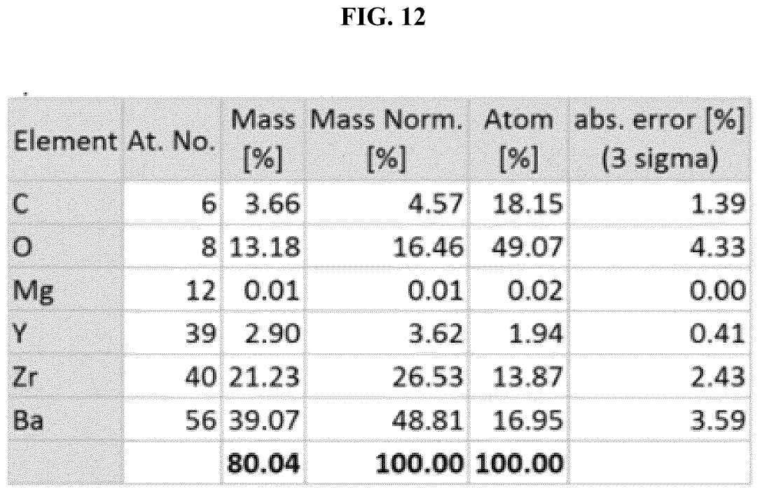

In one embodiment, a composition ratio of barium (Ba), zirconium (Zr), and yttrium (Y) in an ideal BZY composite may be in a range of 1:0.8:0.2 to 1:0.9:0.1. In other words, when the BZY electrolyte film is formed through the composition ratio of barium, zirconium, and yttrium of 1:0.8:0.2 to 1:0.9:0.1, the BZY electrolyte film may be operated at a medium-low temperature (e.g., 500° C. or lower) because it has high performance (i.e., improved ion conductivity). Therefore, it is possible to consider a method of performing single sputtering through one material (e.g., a material related to the barium cerate series such as BZY, BCZY, and BCZYYb) related to the formation of the BZY composite, but as a result of performing the single sputtering process, an amount of barium in the generated outcome significantly decreases, and thus the composition ratio of barium, zirconium, and yttrium is changed, thereby making it impossible to obtain the ideal BZY composite. Therefore, in the present disclosure, BaCO₃, ZrO₂, and Y₂O₃ respectively related to barium, zirconium, and yttrium were contained in each of the multiple targets, and the electrolyte layer related to the BZY composite was formed through co-sputtering using each target. It can be confirmed that when the co-sputtering is performed on the target related to each material (i.e., barium, zirconium, and yttrium) rather than a single material, as illustrated in FIG. 12, an electrolyte layer included in a range set to about 1:0.82:0.11, that is, having an ideal ratio at which a ratio of A site to B site is almost 1:1 is formed.

In one embodiment, the power applied to each of the multiple targets may be in a range of 20 to 200 W. In other words, the power applied to each target may be limited in the range of 20 to 200 W. In other words, the power supply unit 200a may supply the power limited to a range of 20 to 200 W to each of the first target 211, the second target 212, and the third target 213. This power supply limitation range may be for optimizing the stability and performance of the electrolyte layer 130 formed as a result of co-sputtering. In one embodiment, since the conductive electrolyte layer 130 according to the present disclosure is a BZY-based conductive electrolyte, material composition stoichiometry should be secured and a perovskite phase should be implemented. In other words, the range (i.e., 20 to 200 W) of the power applied to the target may be a value obtained by optimizing process variables for material composition.

According to one embodiment, it may be characterized in that the different power is supplied to each of the multiple targets. In the embodiment, since each target is related to a different material, different power (or a different range of available power) may be supplied to each target so that the material is properly deposited on the substrate to form the electrolyte layer. According to the present disclosure, BZY deposition may be performed by controlling the power applied to each target, and in particular, a doping concentration of Y may be smoothly controlled.

In a specific embodiment, the power supplied to the first target 211 related to BaCO₃ may be in a range of 70 to 100 W. In addition, the power supplied to the second target 212 related to ZrO₂ may be in a range of 50 to 80 W. In addition, the power supplied to the third target 213 related to Y₂O₃ may be in a range of 20 to 60 W. As described above, the conductive electrolyte layer 130 according to the present disclosure may be formed only when power is supplied within the limited range related to each target. For example, when power out of a preset power range in correspondence to each target is supplied, the composition of BZY is changed and thus the ion conductivity of the formed electrolyte layer may be reduced.

According to one embodiment, it may be characterized in that the conductive electrolyte layer may be deposited on one surface of the substrate in a thickness of smaller than 2 μm. As the conductive electrolyte layer 130 is formed through the co-sputtering process, the conductive electrolyte layer 130 may become an ultra-thin layer of smaller than 2 μm. The thin electrolyte film may be formed through the thin film deposition using co-sputtering. In addition, it may be characterized in that a deposition area of the conductive electrolyte layer 130 is 2×2 cm² or more. In other words, according to the present disclosure, it is possible to provide an advantageous effect for small thickness and large area by forming the conductive electrolyte using the sputtering process.

Therefore, it is possible to minimize the protonic conduction resistance in a thickness direction of the electrolyte, thereby maximizing conductivity. In other words, a length of ion conduction between electrodes in a fuel cell may be reduced through small thickness, thereby maximizing ion conduction. In this case, since the operating temperature may be significantly lower than a temperature zone in which oxygen ions may be conducted, the operating temperature may be reduced. This can prevent degradation due to the high-temperature operation, thereby providing the effect of improving long-term durability and stability in the process of using the fuel cell. Furthermore, it is possible to provide a high-performance SOFC that may be operated at a medium-low temperature (e.g., 500° C. or lower) (i.e., overcome the limitation of the operating temperature), thereby leading a reduction of carbon dioxide and the expansion and supply of fuel cells.

According to one embodiment of the present disclosure, the method of forming a conductive electrolyte layer may include sintering the conductive electrolyte layer at a set sintering temperature (S150). Here, it may be characterized in that the set sintering temperature is 900° C. or lower. When the sputtering process is performed, since a separate thermal process does not need to be performed, sintering may be performed at a relatively low sintering temperature. For example, BaZrO₃ and BaCeO₃ are widely used as conductive ceramics, and when an electrolyte layer is intended to be formed by performing a wet process, BaCeO₃ requires a sintering temperature of 1400 to 1450° C., and BaZrO₃ requires a sintering temperature of 1600° C. or higher. In the high-temperature thermal process, the high-temperature thermal process may cause degradation of cells due to various mechanisms such as the destruction of a micro-structure of the fuel cell, the formation of a secondary phase, etc. Therefore, according to the present disclosure, it is possible to manufacture the electrolyte layer at the relatively low temperature by performing the thin film deposition process using sputtering. Therefore, it is possible to prevent the destruction of the micro-structure and the formation of the secondary phase, thereby improving performance of the fuel cell.

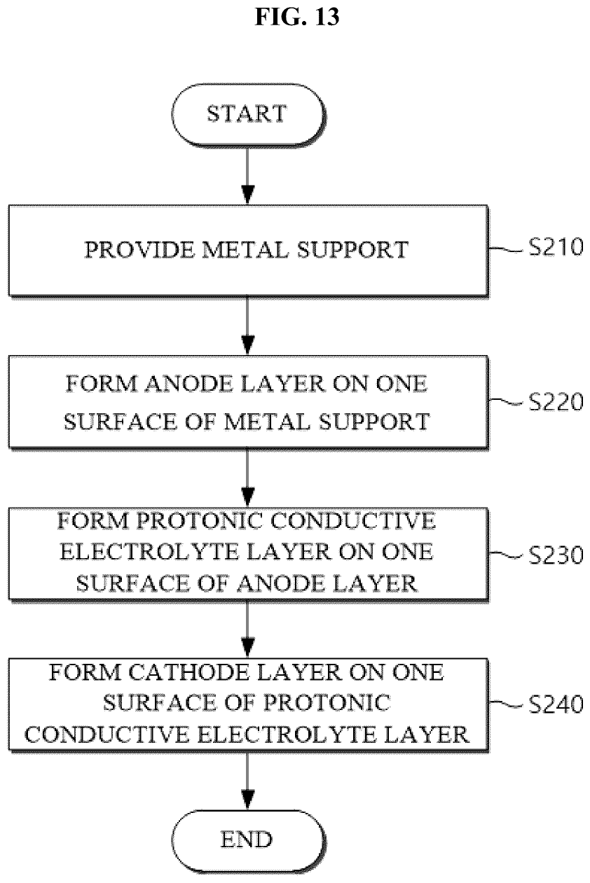

FIG. 13 is a view illustrating an exemplary flowchart of a method of manufacturing an MS-SOFC (i.e., a metal-supported conductive ceramic fuel cell) including a conductive electrolyte layer. The order of operations illustrated in FIG. 13 may be changed, as necessary, and at least one operation may be omitted or added. In other words, the operations of FIG. 13 are only one embodiment of the present disclosure, and the scope of the present disclosure is not limited thereto.

According to one embodiment of the present disclosure, the method of manufacturing the MS-SOFC including the conductive electrolyte layer may include providing a metal support (S210).

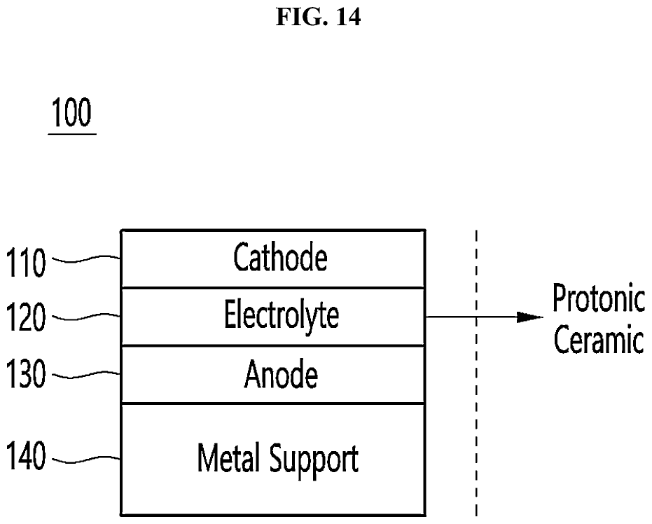

In the embodiment, it may be characterized in that at least a portion of the metal support 110 is made of a porous metal, and the metal support 110 supports an anode layer 120, an electrolyte layer 130, and a cathode layer 140. Referring to FIG. 14, the anode layer 120 may be formed on an upper surface of the metal support 110, the electrolyte layer 130 may be formed on an upper surface of the anode layer 120, and the cathode layer 140 may be formed on an upper surface of the electrolyte layer 130. In an additional embodiment, as illustrated in FIG. 3, an anode functional layer may be provided between the anode (i.e., the anode layer) and the electrolyte layer 130. In one embodiment, the anode functional layer may be formed to have a smaller grain size than the anode and may function to maximize reactivity as it is disposed adjacent to the electrolyte. According to the embodiment, the sputtering process may be advantageous for forming the anode functional layer. Specifically, the anode functional layer having a small-scale micro-structure may be formed through the sputtering process.

According to one embodiment of the present disclosure, the method of manufacturing the MS-SOFC including the protonic conductive electrolyte layer may include forming the anode layer on one surface of the metal support (S220).

In one embodiment, the forming of the anode layer 120 may include loading the metal support into the chamber. The inner space 220a may be present in the sputtering chamber 220, and the metal support 110 may be positioned at the upper side of the support 230 provided in the corresponding inner space 220a. In other words, the anode layer 120, the electrolyte layer 130, and the cathode layer 140 may be deposited using the metal support 110 as a substrate.

In addition, the forming of the anode layer may connect the multiple targets to the chamber. According to one embodiment, the multiple targets may include any one of NiO, BaCO₃, Y₂O₃, ZrO₂, and LSCF

In addition, the forming of the anode layer may include injecting a mixed gas into the chamber. In the embodiment, the mixed gas may include argon and oxygen. The composition ratio of oxygen to argon in the mixed gas may be in a range of 1:3 to 1:10. In other words, argon in the mixed gas may be provided to have a capacity of 3 to 10 times greater than that of oxygen.

More specifically, during co-sputtering, C may be generated from BaCO₃ related to the first target 211, and the generated C may be contained in a BZY composite as an impurity. Therefore, an oxygen partial pressure may be adjusted to prevent C from entering the electrolyte film as an impurity. When the oxygen partial pressure is adjusted, C may be blown away as volatile CO₂ and not contained in the membrane as an impurity. As a specific example, as the oxygen partial pressure increases, C may be better removed. However, when the oxygen partial pressure is too high, a deposition rate is significantly reduced, and thus an oxygen ratio in the mixed gas may be in a range of 10 to 30%. In other words, a minimum oxygen ratio may be 10%, and a maximum oxygen ratio may be 30%. When there is a large amount of oxygen, an amount of oxygen larger than that of stoichiometry may enter the electrolyte film. Therefore, in order to match stoichiometry, oxygen should be neither too much nor too little. In the embodiment, as a method of adjusting supplied oxygen, there are a method of increasing the oxygen partial pressure by increasing the oxygen ratio at the same pressure and a method of increasing the oxygen partial pressure by increasing only the deposition pressure at the same oxygen ratio. In a more specific embodiment, the deposition pressure (or the supply pressure) of the mixed gas may be in a range of 3 to 25 m Torr.

In addition, the forming of the anode layer may include supplying power to at least one of the multiple targets and depositing the anode layer on one surface of the metal support. In a specific embodiment, the anode layer may be deposited on one surface of the metal support by supplying power to targets related to NiO, BaCO₃, Y₂O₃, and ZrO₂. According to the embodiment, it may be characterized in that the anode layer 120 is deposited on one surface of the metal support 110 and is a NiO-BZY composite generated as a result of co-sputtering using at least one (i.e., four target related to NiO, BaCO₃, Y₂O₃, and ZrO₂) of the multiple targets.

According to one embodiment of the present disclosure, the method of manufacturing the MS-SOFC including the protonic conductive electrolyte layer may include forming the conductive electrolyte layer on one surface of the anode layer 120 (S230).

The forming of the conductive electrolyte layer may include supplying power to at least one of the multiple targets and depositing the electrolyte layer on one surface of the substrate. Specifically, the conductive electrolyte layer 130 may be formed on one surface of the anode layer 120 by supplying power to targets related to BaCO₃, Y₂O₃, and ZrO₂.

In the embodiment, the forming of the conductive electrolyte layer may include performing sintering at a set sintering temperature. In this case, it may be characterized in that the set sintering temperature may be 900° C. or lower.

In general, BaZrO₃ and BaCeO₃ are widely used as protonic conductive ceramics. In the embodiment, the sinterability of BaZrO₃ may be relatively lower than that of BaCeO₃. BaCeO₃ requires a sintering temperature of 1400 to 1450° C. for a sintered density of 95% or more, while BaZrO₃ requires a high sintering temperature of 1600° C. or higher. For example, when the sintering temperature is high, the evaporation of Ba may result in formation of a secondary phase such as ZrO₂ having low ionic conductivity. In addition, due to low sinterability, grain growth is not sufficiently implemented even at a temperature of 1600° C. or higher, and thus there is a disadvantage in that a grain boundary resistance is high.

In other words, the MS-PCFC has various advantages such as low operating temperature, structural stability, redox stability, high output, and low price, but there are various factors that hinder performance of fuel cells, such as interfacial reaction between a metal support and a ceramic, chemical stability of an electrolyte, a sintering temperature and limitation of a sintering property, and a process of preparing an electrolyte of a dense thin film.

The present disclosure is directed to minimizing factors that hinder performance of the corresponding fuel cell in a process in providing the MS-PCFC that may have a remarkably lower operating temperature and is advantageous in terms of commercialization. More specifically, since the MS-PCFC (or an MS-SOFC including a protonic conductive electrolyte layer) according to the present disclosure is manufactured in a low-temperature process of 900° C. or lower in a manufacturing process, it is possible to prevent the destruction of a micro-structure, the generation of a secondary phase, and the like, and since the MS-PCFC may be operated at the low operating temperature (e.g., 550° C. or lower), it is possible to prevent degradation of components and at the same time, provide high performance.

According to one embodiment of the present disclosure, the method of manufacturing the MS-SOFC including the conductive electrolyte layer may include forming the cathode layer on one surface of the conductive electrolyte layer (S240). In a specific embodiment, the cathode layer 140 may be deposited on one surface of the electrolyte layer 130 by supplying power to targets related to BaCO₃, Y₂O₃, ZrO₂, and LSCF. According to the embodiment, it may be characterized in that the cathode layer 140 is deposited on one surface of the conductive electrolyte layer and is a LSCF-BZY composite generated as a result of co-sputtering using at least one (i.e., four targets related to BaCO₃, Y₂O₃, ZrO₂, and LSCF) of the multiple targets.

In one embodiment, it may be characterized in that in an MS-SOFC 100 according to the present disclosure, an anode layer, an electrolyte layer, and a cathode layer are sequentially formed through dry processes on one surface of a metal support in a chamber.

In other words, in a process of forming each layer, each layer may be formed at once in a sputtering chamber without a separate thermal process. Specifically, since a simplified process operation compared to a wet process in which a separate high-temperature sintering process is added for each layer is provided, it is possible to provide excellent production efficiency. In other words, since each component formed above the metal support may be formed at once, it is possible to provide high efficiency in terms of mass productivity and economic feasibility.

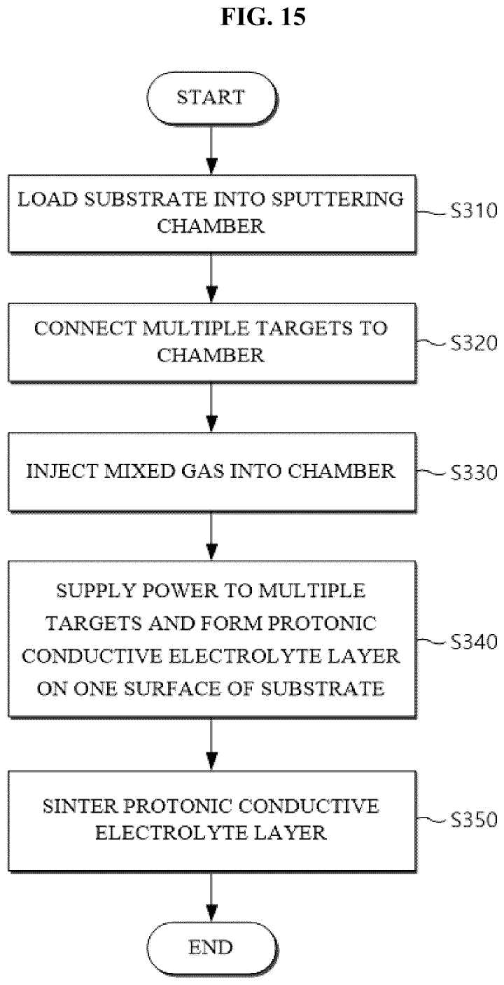

FIG. 15 is a view illustrating an exemplary flowchart of a method of forming a conductive electrolyte layer according to another embodiment (i.e., second embodiment) of the present disclosure. The order of operations illustrated in FIG. 15 may be changed, as necessary, and at least one operation may be omitted or added. In other words, the operations of FIG. 15 are only one embodiment of the present disclosure, and the scope of the present disclosure is not limited thereto.

According to another embodiment of the present disclosure, the method of forming a conductive electrolyte layer may include loading a substrate into a sputtering chamber (S310). It may be characterized in that the conductive electrolyte layer 130 according to the present disclosure is formed through a sputtering process. Referring to FIGS. 5 and 6, the inner space 220a may be present in the sputtering chamber 220, and the substrate 101 may be positioned at the upper side of the support 230 provided in the inner space 220a. In one embodiment, the substrate 101 may mean a plate on which the conductive electrolyte layer 130 is deposited. The substrate 101 may be made of various materials depending on the purpose of use. For example, an anode layer may be used as a substrate. In the embodiment, a heater for heating the substrate 101 or a cooling unit for cooling the substrate 101 may be provided under the substrate 101. In addition, in the embodiment, the substrate 101 may be provided to be rotated for uniform deposition.

When the substrate is positioned in the inner space 220a of the sputtering chamber 220, the multiple targets may be positioned at the upper portion of the inner space 220a. Describing this in more detail with reference to FIG. 6, the pump 240 may make the inner space 220a of the chamber 220 into a vacuum state. Since sputtering should be performed in a vacuum state, condensed air may be discharged through the pump 240 to maintain the vacuum state in the inner space 220a. In a state in which the substrate is loaded into the chamber 220, the inner space 220a may be maintained in the vacuum state through the pump 240.

In the embodiment, the power supply unit 200a may mean a power supply for supplying power to a negative electrode. The power supply unit 200a may be related to DC power and AC power. In a specific embodiment, the power supply unit 200a may use a high frequency (RF) AC power having a preset frequency.

In one embodiment, a gun may be an assembly that mounts a target and is connected to a power supply to act as a negative electrode. Cooling water for cooling the target flows inside the gun, and a wire for receiving power from the power supply unit 200a may be provided therein. The gun may be connected to the target and may perform cooling and supplying power in direct contact with the target.

The target may be a material for coating the substrate 101. According to the present disclosure, co-sputtering using multiple targets 210a may be performed, and each of the multiple targets may be related to BaCO₃ and a YZR alloy. The target is mounted on (or connected to) the gun to substantially function as a surface of the negative electrode, and ions generated from the plasma collide with the target connected to the negative electrode. In this case, as atoms and molecules on the surface of the target bounce off and accumulate on the substrate positioned at an opposite side, a material related to the target is deposited on the substrate.

The shutter 270 may function to mask between the substrate 101 and the target. For example, the shutter 270 may instantaneously block between the substrate 101 and the target in order to perform deposition for a desired time.

The gas supply unit 250 may supply gases into the chamber. Here, a gas supplied by the gas supply unit 250 may be related to an argon gas. In a more specific embodiment, the gas supply unit 250 may supply a mixed gas in which argon and oxygen are mixed at a preset ratio into the chamber. The gas supply unit 250 may include a gas supply module in correspondence to each gas. For example, the gas supply unit 250 may include a first gas supply module corresponding to argon and a second gas supply module corresponding to oxygen. A mass flow controller (MFC) may be provided in each gas supply module, and thus an accurate amount of gas may be injected into the chamber. For example, the MFC may control the supply of an accurate amount of gas (e.g., argon and oxygen) into the chamber by measuring an amount of gas in a unit of sccm. In addition, a shield may be provided on a portion of an outer circumferential surface of the target. The shield 260 may be provided to allow sputtering to be performed on only a desired portion of the connected target and maintain stability of discharge.

According to another embodiment of the present disclosure, a method of forming a conductive electrolyte layer may include connecting the multiple targets 210a to the chamber (S320).

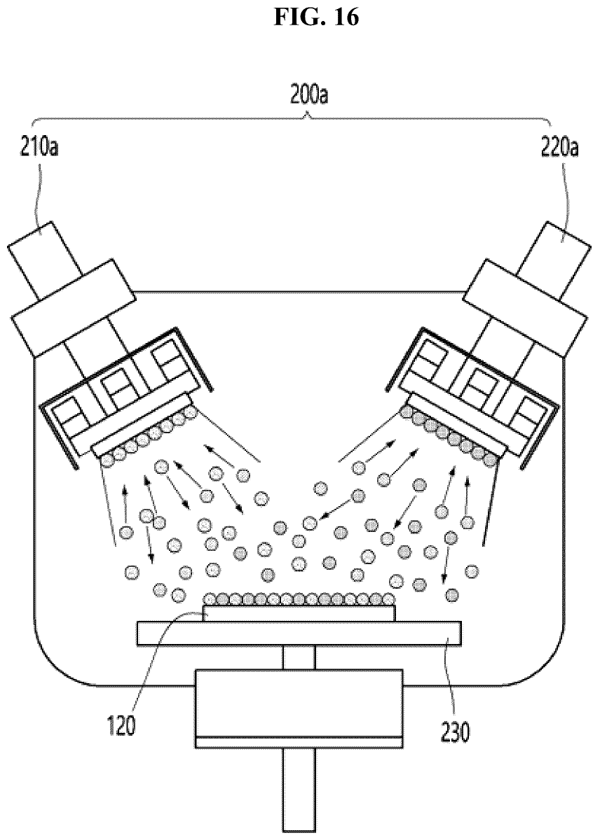

In one embodiment, the multiple targets 210a may include targets related to each of BaCO₃ and a YZR alloy. In other words, as illustrated in FIG. 16, according to the present disclosure, the conductive electrolyte layer 130 may be formed through co-sputtering using the first target 211a related to BaCO₃ and the second target 211b related to the YZR alloy.

According to the embodiment, it may be characterized in that the YZR alloy is an alloy containing zirconium (Zr) and yttrium (Y), and a ratio of zirconium to yttrium in the YZR alloy may be in a range of 8:2 to 9:1. In other words, as a result of co-sputtering using the first target 211a related to BaCO₃ and the second target 211b related to the YZR alloy, the conductive electrolyte layer 130 related to the BZY composite may be formed. In this case, since ZY is deposited using an alloy related to zirconium and yttrium, the number of targets used for co-sputtering may be reduced as compared to the first embodiment. Therefore, the number of variables in the process can be further reduced, and process operations can also be simplified. For example, since the YZR alloy according to the present disclosure is formulated to contain a certain ratio of zirconium to yttrium (i.e., a ratio of zirconium to yttrium is in a range of 8:2 to 9:1), when co-sputtering is performed using the corresponding target and the target related to BaCO₃, an electrolyte layer related to a BZY composite (i.e., a composite in which a composition ratio of barium, zirconium, and yttrium is in a range of 1:0.8:0.2 to 1:0.9:0.1), which is thin and dense and thus has improved performance and may be operated at a medium-low temperature, may be formed.

According to another embodiment of the present disclosure, the method of forming a conductive electrolyte layer may include injecting a mixed gas into the chamber (S330). In the embodiment, the mixed gas may include argon and oxygen. The composition ratio of oxygen to argon in the mixed gas may be in a range of 1:3 to 1:10. In other words, argon in the mixed gas may be provided to have a capacity of 3 to 10 times greater than that of oxygen.

More specifically, during co-sputtering, C may be generated from BaCO₃ related to the first target 211a, and the generated C may be contained in the BZY composite as an impurity. Therefore, an oxygen partial pressure may be adjusted to prevent C from entering the electrolyte film as an impurity. When the oxygen partial pressure is adjusted, C may be blown away as volatile CO₂ and not contained in the membrane as an impurity. As a specific example, as the oxygen partial pressure increases, C may be better removed. However, when the oxygen partial pressure is too high, a deposition rate is significantly reduced, and thus an oxygen ratio in the mixed gas may be in a range of 10 to 30%. In other words, a minimum oxygen ratio may be 10%, and a maximum oxygen ratio may be 30%. When there is a large amount of oxygen, an amount of oxygen larger than that of stoichiometry may enter the electrolyte film. Therefore, in order to match stoichiometry, oxygen should be neither too much nor too little. In the embodiment, as a method of adjusting supplied oxygen, there are a method of increasing the oxygen partial pressure by increasing the oxygen ratio at the same pressure and a method of increasing the oxygen partial pressure by increasing only the deposition pressure at the same oxygen ratio. In a more specific embodiment, the deposition pressure (or the supply pressure) of the mixed gas may be in a range of 3 to 25 m Torr.

According to another embodiment of the present disclosure, the method of forming a conductive electrolyte layer may include supplying power to each of the multiple targets and forming the conductive electrolyte layer on one surface of the substrate multiple targets 210a (S340).

According to the embodiment, the present disclosure may be characterized by performing the co-sputtering process using the multiple targets. According to one embodiment, the conductive electrolyte layer 130 may be the BZY composite formed through the deposition process using the multiple targets. It may be characterized in that the BZY composite is a barium zirconate composite (Y:BaZrO₃) doped with yttrium. It may be characterized in that a composition ratio of barium, zirconium, and yttrium in the BZY composite is in a range of 1:0.8:0.2 to 1:0.9:0.1. The present disclosure is directed to forming the electrolyte layer related to the BZY composite that is thin and dense, has improved performance, and may be operated even at a medium-low temperature.

In one embodiment, a composition ratio of barium (Ba), zirconium (Zr), and yttrium (Y) in an ideal BZY composite may be in a range of 1:0.8:0.2 to 1:0.9:0.1. In other words, when the BZY electrolyte film is formed through the composition ratio of barium, zirconium, and yttrium of 1:0.8:0.2 to 1:0.9:0.1, the BZY electrolyte film may be operated at a medium-low temperature (e.g., 500° C. or lower) because it has high performance (i.e., improved ion conductivity). Therefore, it is possible to consider a method of performing single sputtering through one material (e.g., a material related to the barium cerate series such as BZY, BCZY, and BCZYYb) related to the formation of the BZY composite, but as a result of performing the single sputtering process, an amount of barium in the generated outcome significantly decreases, and thus the composition ratio of barium, zirconium, and yttrium is changed, thereby making it impossible to obtain the ideal BZY composite. Therefore, according to the present disclosure, BaCO₃ related to each of barium, zirconium, and yttrium, and the YZR alloy are contained in each of the multiple targets, and an electrolyte layer related to the BZY composite may be formed through co-sputtering using each target. When the co-sputtering is performed using the target related to each material (i.e., barium, zirconium, and yttrium) rather than a single material, an electrolyte layer included in a range set to about 1:0.82:0.11, that is, having an ideal ratio at which a ratio of A site to B site is almost 1:1 may be formed.

In one embodiment, the power applied to each of the multiple targets may be in a range of 20 to 200 W. In other words, the power applied to each target may be limited to a range of 20 to 200 W. In other words, the power supply unit 200a may supply the power limited to a range of 20 to 200 W to each of the first target 211a and the second target 211b. This power supply limitation range may be for optimizing the stability and performance of the electrolyte layer 130 formed as a result of co-sputtering. In one embodiment, since the conductive electrolyte layer 130 according to the present disclosure is a BZY-based conductive electrolyte, material composition stoichiometry should be secured and a perovskite phase should be implemented. In other words, the range (i.e., 20 to 200 W) of the power applied to the target may be a value obtained by optimizing process variables for material composition. According to one embodiment, it may be characterized in that different power is supplied to each of the multiple targets 210a. In the embodiment, since each target is related to a different material, different power (or a different range of available power) may be supplied to each target so that the material is properly deposited on the substrate to form the electrolyte layer. According to the present disclosure, BZY deposition may be performed by controlling the power applied to each target, and in particular, a doping concentration of Y may be smoothly controlled.

According to the embodiment, it may be characterized in that the conductive electrolyte layer may be deposited on one surface of the substrate in a thickness of smaller than 2 μm. As the conductive electrolyte layer 130 is formed through the co-sputtering process, the conductive electrolyte layer 130 may become an ultra-thin layer of smaller than 2 μm. The thin electrolyte film may be formed through the thin film deposition using co-sputtering. In addition, it may be characterized in that a deposition area of the conductive electrolyte layer 130 is 2×2 cm² or more. In other words, according to the present disclosure, it is possible to provide an advantageous effect for small thickness and large area by forming the conductive electrolyte using the sputtering process.

Therefore, it is possible to minimize the protonic conduction resistance in a thickness direction of the electrolyte, thereby maximizing conductivity. In other words, a length of ion conduction between electrodes in a fuel cell may be reduced through small thickness, thereby maximizing ion conduction. In this case, since the operating temperature may be significantly lower than a temperature zone in which oxygen ions may be conducted, the operating temperature may be reduced. This can prevent degradation due to the high-temperature operation, thereby providing the effect of improving long-term durability and stability in the process of using the fuel cell. Furthermore, it is possible to provide a high-performance SOFC that may be operated at a medium-low temperature (e.g., 500° C. or lower) (i.e., overcome the limitation of the operating temperature), thereby leading a reduction of carbon dioxide and the expansion and supply of fuel cells.

According to another embodiment of the present disclosure, the method of forming a conductive electrolyte layer may include sintering the conductive electrolyte layer (S350).

In one embodiment, it may be characterized in that the sintering of the conductive electrolyte layer includes sintering the conductive electrolyte layer using optical sintering. In one embodiment, the optical sintering may mean forming a perovskite crystal structure in the conductive electrolyte layer by irradiating ultrashort wave white light having an energy of 60 to 70 J on the conductive electrolyte layer. More specifically, before irradiating the ultrashort wave white light having the energy of 60 to 70 J, a drying process for removing moisture is performed, and the conductive electrolyte layer may be thermally decomposed by irradiating the ultrashort wave white light having energy lower than the energy of 60 to 70 J. In the embodiment, a dryer used in the drying process performed to remove moisture may be, for example, at least one of a vacuum oven, a heater, or a hot plate. This drying process may be performed, for example, at a temperature of lower than 200° C. In the embodiment, the ultrashort wave white light used in the thermal decomposition process may be microwave light. According to the embodiment, the conductive electrolyte layer may be irradiated with the ultrashort wave white light having the energy lower than 60 to 70 J using arc plasma generated by applying a high electric current to a Xenon flash lamp. For example, a pulse width of the Xenon flash lamp may be in a range of 0.1 to 100 ms, a pulse gap of the Xenon flash lamp may be in a range of 0.1 to 100 ms, the number of pulses of the Xenon flash lamp may be in a range of 1 to 1000 times, and an intensity of the Xenon flash lamp may be in a range of 0.01 to 100 J/cm². In addition, a time for which the ultrashort wave white light is irradiated in the thermal decomposition process may be, for example, several milliseconds.

In addition, in the embodiment, after the drying process and the thermal decomposition process are performed, a sintering process of irradiating the ultrashort wave white light having the energy of 60 to 70 J may be performed. When the conductive electrolyte layer 130 is irradiated with the ultrashort wave white light having the energy of 60 to 70 J, a perovskite crystal structure may be formed in the conductive electrolyte layer 130. In other words, the ultrashort wave white light having the energy of 60 to 70 J is irradiated to grow a perovskite crystal in the conductive electrolyte layer 130, and at the same time, the conductive electrolyte layer 130 may be sintered to manufacture a thin film. In this case, since energy is applied for a short time in a unit of millisecond to a local portion requiring sintering in a room temperature environment by the Xenon flash lamp, it is possible to minimize damage and deformation of the substrate, thereby reducing a process cost and a process time.

It may be characterized in that the sintering temperature related to the optical sintering is 500° C. or lower. When the sputtering process is performed, since a separate thermal process does not need to be performed, sintering may be performed at a relatively low sintering temperature. For example, BaZrO₃ and BaCeO₃ are widely used as conductive ceramics, and when an electrolyte layer is intended to be formed by performing a wet process, BaCeO₃ requires a sintering temperature of 1400 to 1450° C., and BaZrO₃ requires a sintering temperature of 1600° C. or higher. In the high-temperature thermal process, the high-temperature thermal process may cause degradation of cells due to various mechanisms such as the destruction of a micro-structure of the fuel cell, the formation of a secondary phase, etc. Therefore, according to the present disclosure, it is possible to manufacture the electrolyte layer at the relatively low temperature by performing the thin film deposition process using sputtering. Therefore, it is possible to prevent the destruction of the micro-structure and the formation of the secondary phase, thereby improving performance of the fuel cell.

In particular, the optical sintering may selectively sinter only the electrolyte, unlike thermal sintering, and thus has an advantage in that it is possible to solve the problem of the high-temperature thermal sintering process and significantly further reduce (i.e., 500° C. or lower) the sintering temperature than the sintering temperature (e.g., 900° C.) in the first embodiment. In other words, it is possible to finish sintering within a short time (e.g., 1 second), thereby significantly reducing the process time and cost.

According to various embodiments of the present disclosure, it is possible to provide a metal-supported conductive ceramic fuel cell with improved performance by manufacturing a fuel cell through relatively low-temperature dry processes. In other words, it is possible to solve problems such as the destruction of a micro-structure, the destruction of a composition due to mutual diffusion, and the generation of a secondary phase, thereby improving the durability and performance of the fuel cell.

In addition, according to the present disclosure, it is possible to provide a fuel cell with finally improved durability and stability by implementing a metal-supported conductive ceramic fuel cell at a low operating temperature to minimize various thermal problems in a process of using the fuel cell.

In addition, according to the present disclosure, it is possible to provide an advantageous effect for small thickness and large area by forming a conductive electrolyte using a sputtering process.

In addition, according to the present disclosure, it is possible to improve productivity of a process by simultaneously performing sputtering and solid-state reactive sintering (SSRS) so that deposition of a thin film, formation of a phase, densification, and grain growth are performed at once.

Effects of the present disclosure are not limited to the above-described effects, and other effects that are not mentioned will be able to be clearly understood by those skilled in the art from the following description.

Although embodiments of the present disclosure have been described above with reference to the accompanying drawings, those skilled in the art to which the present disclosure pertains will be able to understand that the present disclosure can be carried out in other specific forms without changing the technical spirit or essential features thereof. Therefore, it should be understood that the above-described embodiments are illustrative and not restrictive in all respects.

Specific implementations described in the present disclosure are embodiments and do not limit the scope of the present disclosure in any way. For simplicity of the specification, description of conventional electronic components, control systems, software, and other functional aspects of the systems may be omitted. In addition, the connection of lines or connecting members between the components illustrated in the drawings are examples of functional connections and/or physical or circuit connections and may be illustrated as various functional connections, physical connection, or circuit connections to be replaced or added. In addition, when there is no specific mention such as “essential” or “important,” the corresponding component may not necessarily be a component necessary for applying the present disclosure.

It should be understood that the specific orders or hierarchies of operations in the suggested processes are an approachable exemplary example. Based on design priorities, it should be understood that the specific orders or hierarchies of the operations in the processes may be rearranged within the scope of the present disclosure. The accompanying method claims provide elements of various operations in a sample order but are not meant to be limited to the suggested specific orders or hierarchies.

The description of the suggested embodiments is provided so that those skilled in the art may use or practice the present disclosure. Various modifications to these embodiments will be apparent to those skilled in the art, and the general principles defined herein may be applied to other embodiments without departing from the scope of the present disclosure. Therefore, the present disclosure is not limited to the embodiments suggested herein, but should be construed in the widest scope consistent with the principles and novel features suggested herein.

What is claimed is:

1. A method of forming a conductive electrolyte layer, comprising:
loading a substrate into a sputter chamber;
connecting a plurality of targets to the chamber;
injecting a mixed gas into the chamber;
supplying power to each of the plurality of targets and forming a conductive electrolyte layer on one surface of the substrate; and
sintering the conductive electrolyte layer at a set sintering temperature.

2. The method of claim 1, wherein the mixed gas includes argon (Ar) and oxygen (O₂),
a composition ratio of oxygen to argon is in a range of 1:3 to 1:10, and
a supply pressure of the mixed gas is in a range of 3 to 25 m Torr.

3. The method of claim 1, wherein the set sintering temperature is 900° C. or lower, and
a rotation speed of the substrate in the chamber is 900 RPM or less.

4. The method of claim 1, wherein the conductive electrolyte layer is a BZY composite formed through a deposition process, and
the BZY composite is a barium zirconate composite (Y:BaZrO₃) doped with yttrium.

5. The method of claim 4, wherein a composition ratio of each of barium (Ba), zirconium (Zr), and yttrium (Y) in the BZY composite is in a range of 1:0.8:0.2 to 1:0.9:0.1.

6. The method of claim 1, wherein the plurality of targets include:
a first target including BaCO₃;
a second target including ZrO₂; and
a third target including Y₂O₃, and
the power applied to each of the plurality of targets is in a range of 20 to 200 W.

7. The method of claim 6, wherein the power supplied to the first target is in a range of 70 to 100 W,
the power supplied to the second target is in a range of 50 to 80 W, and
the power supplied to the third target is in a range of 20 to 60 W.

8. The method of claim 1, wherein the conductive electrolyte layer is deposited on the one surface of the substrate in a thickness of smaller than 2 μm, and a deposition area is 2×2 cm² or more.

9. A method of forming a conductive electrolyte layer, comprising:
supplying power to each of a plurality of targets and forming an electrolyte layer on one surface of a substrate; and
sintering the electrolyte layer at a set sintering temperature,
wherein the set sintering temperature is 900° C. or lower.

10. A method of manufacturing a metal-supported solid oxide fuel cell including a conductive electrolyte layer, the method comprising:
providing a metal support;
forming an anode layer on one surface of the metal support;
forming the conductive electrolyte layer on one surface of the anode layer; and
forming a cathode layer on one surface of the conductive electrolyte layer.

11. The method of claim 10, wherein, in the metal-supported solid oxide fuel cell, the anode layer, the electrolyte layer, and the cathode layer are sequentially formed through dry processes on the one surface of the metal support in a chamber.

12. The method of claim 10, wherein at least a portion of the metal support is made of a porous metal, and the metal support supports the anode layer, the electrolyte layer, and the cathode layer.

13. The method of claim 10, wherein the forming of the anode layer includes:
loading the metal support into a chamber;
connecting a plurality of targets to the chamber;
injecting a mixed gas into the chamber; and
supplying power to at least one of the plurality of targets and depositing the anode layer on the one surface of the metal support.

14. The method of claim 13, wherein each of the plurality of targets includes any one of NiO, BaCO₃, Y₂O₃, ZrO₂, and LSCF.

15. The method of claim 13, wherein the mixed gas includes argon (Ar) and oxygen (O₂),
a composition ratio of oxygen to argon is in a range of 1:3 to 1:10, and
a supply pressure of the mixed gas is in a range of 3 to 25 m Torr.

16. The method of claim 14, wherein the forming of the conductive electrolyte layer further includes:
supplying power to at least one of the plurality of targets and depositing an electrolyte layer on one surface of a substrate; and
performing sintering at a preset sintering temperature,
the preset sintering temperature is 900° C. or lower, and
a rotation speed of the substrate in the chamber is 900 RPM or less.

17. The method of claim 10, wherein the conductive electrolyte layer is a BZY composite formed through a deposition process, and
the BZY composite is a barium zirconate composite (Y:BaZrO₃) doped with yttrium.

18. The method of claim 17, wherein a composition ratio of each of barium (Ba), zirconium (Zr), and yttrium (Y) in the BZY composite is in a range of 1:0.8:0.2 to 1:0.9:0.1.

19. The method of claim 14, wherein the cathode layer is deposited on the one surface of the conductive electrolyte layer and is an LSCF-BZY composite generated as a result of co-sputtering using at least one of the plurality of targets.

20. A metal-supported solid oxide fuel cell including a conductive electrolyte layer, comprising:
a metal support;
an anode layer formed on one surface of the metal support;
the conductive electrolyte layer formed on one surface of the anode layer; and
a cathode layer formed on one surface of the conductive electrolyte layer,
wherein the conductive electrolyte layer is a barium zirconate composite (Y:BaZrO₃) doped with yttrium.

21. A conductive electrolyte layer comprising a barium zirconate composite (Y:BaZrO₃) doped with yttrium,
wherein the barium zirconate composite is formed by being deposited through co-sputtering using a plurality of targets.
